(19) United States
(12) Patent Application Publication
(10) Pub. No.: US 2025/0204024 A1
(43) Pub. Date: Jun. 19, 2025

(54) MOSFET WITH SINGLE CHANNEL IN THE UNIT CELL

(71) Applicant: The Research Foundation for the State University of New York, Albany, NY (US)

(72) Inventors: Woongje Sung, Albany, NY (US); Dongyoung Kim, Albany, NY (US); Justin Lynch, Albany, NY (US)

(21) Appl. No.: 18/982,660

(22) Filed: Dec. 16, 2024

Related U.S. Application Data
(60) Provisional application No. 63/610,745, filed on Dec. 15, 2023.

(51) Int. Cl. H10D 84/00; H10D 62/10; H10D 62/832

(52) U.S. Cl. CPC H10D 84/156; H10D 62/109; H10D 62/8325

(57) ABSTRACT

A MOSFET device having a single channel in a traditional dual-channel MOSFET cell layout. The invention uses both a split gate and single channel to improve the capacitance of the fabricated devices with minimal effect on the static performance. The MOSFET cell is on a substrate and has a first P-well and second P-well, with a gate formed over only a portion of the first P-well, the gate extending a predetermined distance but not over the second P-well. A single channel is then selectively created upon the application of a predetermined voltage to the gate. The second P-well structure can be used to create other devices, such as a Schottky diode or a P+ region.

### CROSS-REFERENCE TO RELATED APPLICATION

This invention claims the benefit of U.S. Provisional Patent Application No. 63/610,745, filed on Dec. 15, 2023, the entirety of which is hereby incorporated herein by this reference.

### STATEMENT REGARDING FEDERALLY SPONSORED RESEARCH

This invention was made with government support under grant number NSF-IIP-2126732, awarded by the National Science Foundation. The government has certain rights in this invention.

### BACKGROUND OF THE INVENTION

### 1. Field of the Invention

The present invention generally relates to semiconductors and methods of their fabrication. More particularly, the present invention is for a MOSFET cell with a single channel for reduced input capacitance, which provides the ability to implement a split-gate approach at reduced cell widths without compromising on-state performance.

### 2. Description of the Related Art

Metal-oxide-semiconductor field-effect transistors (MOSFETs) are often used in the power system components of analog circuits and digital circuits. In order to reduce the power loss of MOSFETs, the specific on-resistance (Ron,sp) must be reduced and a common way to do so is to increase the doping concentration of the epitaxial layer. However, if the doping concentration is increased, then the breakdown voltage cannot remain, which illustrates the problem between breakdown voltage and R_{on,sp}. To address this problem, a “split-gate MOSFET” structure has been developed to maintain the breakdown voltage and reduce the R_{on,sp} in recent years, as well as reduce the capacitances such as input capacitance (Ciss), and miller capacitance (Cgd).

One version of the split-gate MOSFET has another electrode under the gate electrode. The top gate is connected to the positive electrode and the split electrode is a negative electrode connected to the source terminal. The electric field can be extended downward by the split electrode where the breakdown voltage is higher at the same doping concentration of the epitaxial layer. When the breakdown voltage is the same as a single-gate MOSFET, the specific on-resistance can be significantly reduced. Further, a split-gate MOSFET can reduce the stray capacitance (Cgd) between gate and drain, as well as the charge storage effect between gate and drain, by utilizing the bottom gate and oxide layers, thereby, improving the switching speed of the power device

However, extant split-gate MOSFETs poorly manage the space utilization of a chip as they maintain existing cell size and footprint to a specific. This can be a critical issue for chips having space constraints for on-chip devices.

Further, medium voltage power electronic systems using MOSFETs are in applications including rail traction, fast chargers, and grid transmissions. Current systems rely on the use of 6.5 kV Si IGBTs (Insulated Gate Bipolar Transistors) as the main components of the power electronic circuits. The mature Si IGBT offers reliable operation, but due to its bipolar operation, it suffers from poor switching performance.

Further improvements in MOSFET devices are required to provide improvements, such as enabling high-frequency operation, whereby losses are associated with switching and on-state resistance are minimized. Additionally, further development and demonstration of efficient and reliable 6.5 kV 4H-SiC MOSFETs is warranted to facilitate and expand their adoption in medium voltage power electronic systems to improve system size and efficiency. It is thus to such improvements in a single-channel, split gate MOSFET that the present invention is primarily directed.

### BRIEF SUMMARY OF THE INVENTION

Briefly described, the present system and method new layout approach for SiC MOSFETs with a one-channel layout. This approach implements both a split gate and single channel to improve the capacitance of the fabricated device with minimal effect on the static performance.

In an embodiment, the invention utilizes SiC-based power devices offer a potential pathway to improve the performance of medium voltage power electronic systems. Due to a wide bandgap and high critical electric field, the drift layers that are needed to block 6.5 kV can be made thinner and less resistive on SiC compared to Si. With a thinner and less resistive drift layer, unipolar SiC devices, specifically the power SiC MOSFET, can be employed in power electronic systems typically designed with Si bipolar devices. At the 6.5 kV voltage rating, the use of SiC MOSFETs can lead to an increase in the dynamic performance of power electronic systems. In addition, SiC also offers the potential for use in harsh environment applications as SiC has a high thermal conductivity and low intrinsic carrier concentration.

In an embodiment, the invention includes a MOSFET cell having a single channel, with the cell on a substrate and there is a first P-well on the substrate, the first P-well having a top surface thereof, and a first N-doped region on, at least, a portion of the top surface of the first P-well. There is also a second P-well on the substrate adjacent to the first P-well, with the second P-well having a top surface thereof, and the second P-well spaced from the first P-well to form a drain. The second P-well can also be connected to a source as well. There is a second N-doped region on, at least, part of the top surface of second P-well and a gate is formed over a portion the first P-well and a portion of the first N-doped region. The gate extending a predetermined distance over the drain and a single channel is selectively created from the gate to the drain upon the application of a predetermined voltage to the gate.

The gate can be formed from polysilicon and the first P-well and second P-well are implanted by Al. The first N-doped region and second N-doped region can be formed with nitrogen implantation, and the second P-well can include a P+ implant.

The MOSFET cell can be embodied with a JFET formed near the drain. Further, the second P-well and second N-doped region can be used to form other electronic devices, such as a Schottky diode.

In a further embodiment, the invention includes a semiconductor structure formed in a MOSFET cell that is otherwise configured to create two gate channels between a gate and two adjacent P-wells. The semiconductor structure includes a substrate, with a first P-well on the substrate and having a top surface thereof. There is a first N-doped region on, at least, a portion of the top surface of the first P-well. A second P-well is on the substrate adjacent to the first P-well, the second P-well having a top surface thereof and the second P-well spaced from the first P-well

There is a second N-doped region on, at least, part of the top surface of second P-well and a gate is formed over a portion the first P-well and a portion of the first N-doped region over a portion of the first P-well, with the gate further extending a predetermined distance over the drain away from the second P-well and second N-doped region. A single channel is selectively created from the gate to the drain upon the application of a predetermined voltage to the gate.

In another embodiment, the invention includes a semiconductor device that has a plurality of MOSFET devices on a substrate. There is a first MOSFET device on the substrate which has a first P-well on the substrate, the first P-well having a top surface thereof, a first N-doped region on, at least, a portion of the top surface of the first P-well, and a second P-well on the substrate adjacent to the first P-well. The second P-well has a top surface thereof and the second P-well is spaced from the first P-well to form a drain. There is a second N-doped region on, at least, part of the top surface of second P-well and a gate is formed over a portion the first P-well and a portion of the first N-doped region, with the gate extending a predetermined distance over the drain. A single channel is selectively created from the gate to the drain upon the application of a predetermined voltage to the gate.

There is, at least, a second MOSFET device on the substrate adjacent to the second P-well of the first MOSFET cell, with the second P-well and second N-doped region of the first MOSFET device extending into the second MOSFET device. The second MOSFET cell further has a second gate that does not extend over any portion the second P-well and second N-doped region of the first MOSFET device (which would have been the second channel of the first MOSFET) extending into the second MOSFET device.

The present invention therefore provides an advantage in improving the capacitance of the fabricated MOSFET devices with minimal effect on the static performance. Furthermore, the present invention is industrially applicable in the manufacture of MOSFETs, JFETs and other semiconductor devices. These and other objects, advantages, and features will be apparent to one of skill in the art after review of the present application.

### BRIEF DESCRIPTION OF THE DRAWINGS

FIG. 1A is a schematic 3D layout of fabricated prior art conventional MOSFET.

FIG. 1B is a cross-sectional scanning electron microscope (SEM) image of the prior art conventional MOSFET in FIG. 1A.

FIG. 2A is a schematic 3D layout of one embodiment of the single-channel MOSFET.

FIG. 2B is a cross-sectional SEM image of the single-channel MOSFET of FIG. 2A.

FIG. 3A is a graph of a simulated electric field within the gate oxide for the conventional MOSFET and one-channel MOSFET.

FIG. 3B is a graph of the peak electric field within the gate oxide during forward operation of the devices.

FIG. 4 is a graph of a measured IGSS characteristics of a conventional MOSFET and single-channel MOSFET.

FIG. 5A is a graph of the measured output curves of a conventional MOSFET.

FIG. 5B is a graph of the measured output curves of a single-channel MOSFET.

FIG. 6 is a graph of the measured transfer curves for the conventional MOSFET and single-channel MOSFET.

FIG. 7 is a graph of third quadrant output of the conventional MOSFET and single-channel MOSFET.

FIG. 8A is a graph of the measured output curves of a conventional MOSFET at various temperatures.

FIG. 8B is a graph of the measured output curves of a single-channel MOSFET at various temperatures.

FIG. 9 is a graph of the effect of temperature on specific on-resistance and threshold voltage for the conventional MOSFET and one-channel MOSFET.

FIG. 10 is a graph of the measured forward blocking behaviors for the conventional MOSFET and single-channel MOSFET.

FIG. 11 is a graph of the measured capacitance curves for the conventional MOSFET and one-channel MOSFET.

FIG. 12 is schematic diagram of one embodiment of the single-channel MOSFET including a JFET region.

FIG. 13 is schematic diagram of one embodiment of the single-channel MOSFET including a JFET region and a P+ implant to the P-well.

FIG. 14 is a graph of the R_{on,sp} as affected by JFET width.

### DETAILED DESCRIPTION OF THE INVENTION

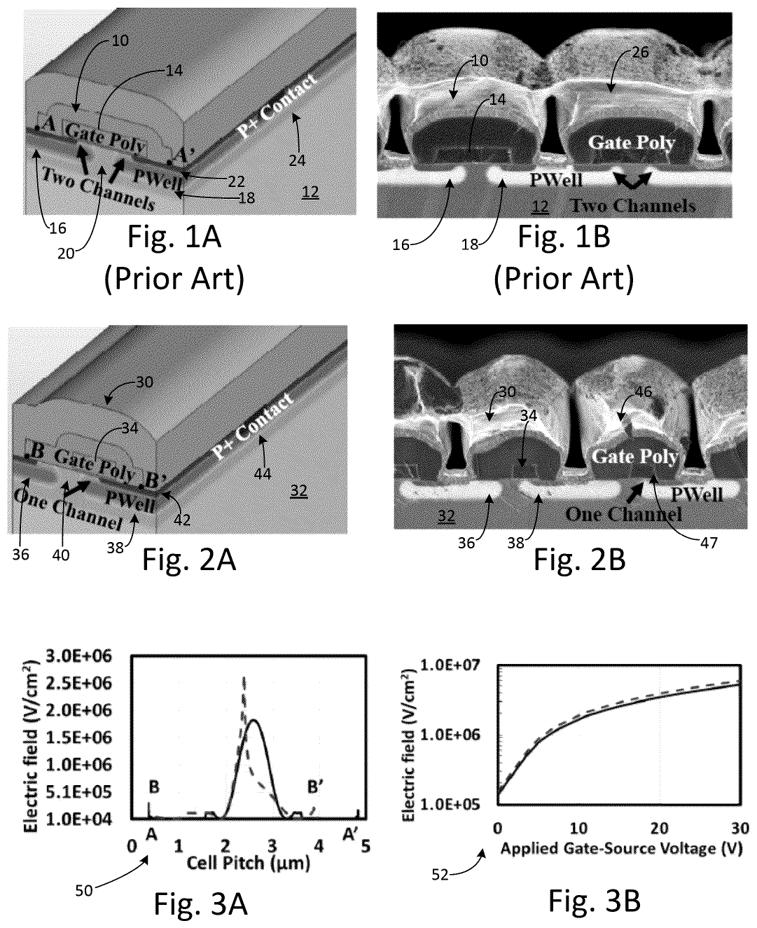

With reference to the figures in which like numerals represent like elements throughout the several views, FIG. 1A is a schematic 3D layout of fabricated prior art conventional MOSFET 10. On a traditional substrate 12, a gate 14 sits atop two P-wells 16,18 creating a drain 20 between the P-wells 16,18 such that two channels are created under the gate 14. There is a N-doped layer 22 on top of at least part of the P-well 16,18. In this extant version a P+ contact 24 is also shown for the MOSFET 10.

FIG. 1B is a cross-sectional scanning electron microscope (SEM) image of the prior art conventional MOSFET 10 in FIG. 1A. Shown is series of MOSFETS 10 and 26 in sequence, with the P-well 18 shared between the MOSFETS 10,26. Each MOSFET 10,26 has two channels.

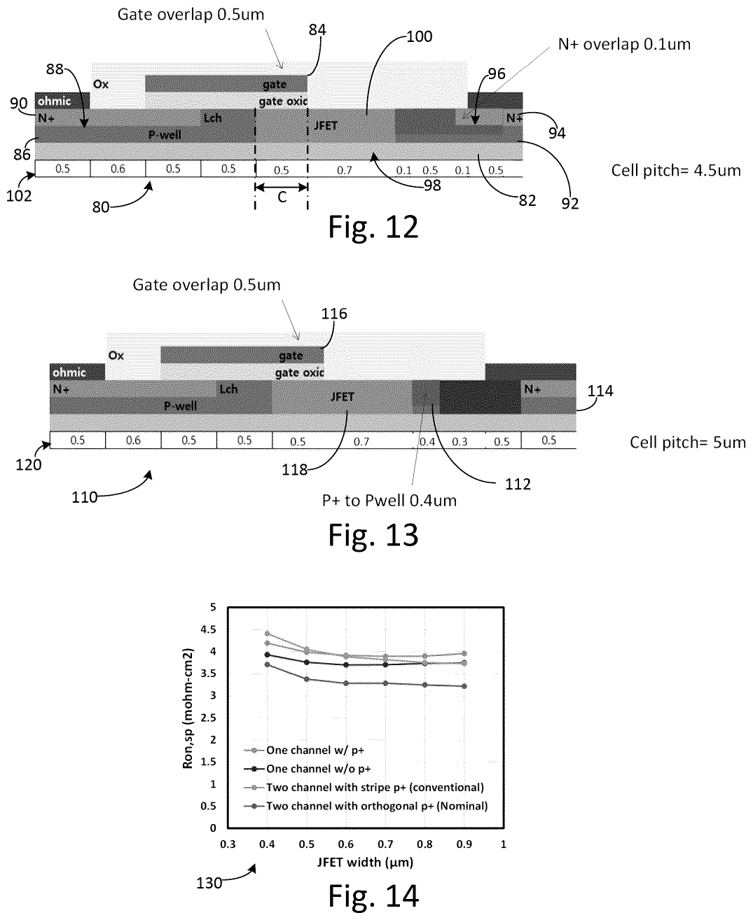

FIG. 2A is a schematic 3D layout of one embodiment of the single-channel MOSFET 30 on a substrate 32. The gate 34 does not extend over two P-wells 36,38 as is shown in the prior art MOSFET 10 in FIG. 1A. Here, the gate 34 extends over P-well 38 and partially over a drain region 40 (a drain terminal is not shown). An N-doped region 42 extends partially over the P-wells 36,38, and the gate 34 extends over the N-doped region 42, P-well 38 and drain region 40. This embodiment also include a P+ contact region 44. Embodiments of the inventive single channel structure are further shown and described below in FIGS. 12 and 13.

FIG. 2B is a cross-sectional SEM image of the single-channel MOSFET 30 of FIG. 2A, and including a second novel MOSFET 46 to illustrate the uses of multiple single-channel MOSFETS on the same substrate 32. Here, the gate 34 is over one P-well 38 that is in connection with the second single-channel MOSFET 46. The P-well 38 and corresponding N-doped region 42 can be used as a separate semiconductor device in single-channel MOSFET 46, such as a Schottky diode (not shown), a P+ inclusion as shown in FIG. 13, or other device as would be known to one of skill in the art.

In this embodiment, the single-channel approach can be implemented through the removal of the gate 34 poly above one of the P-Wells (P-well 36) in an otherwise traditional MOSFET cell 10 (FIG. 1A). Using a one-channel approach for SiC MOSFETS is beneficial for the following reasons: (1) Significant reduction in input capacitance for improvement for high-frequency operation; (2) Removes any concern with channel mismatch within the MOSFET cell, as only one channel is present; (3) Removal of the second channel allows for innovative device architectures, with space within the cell to integrate additional features (e.g., Schottky diode) without increasing the cell pitch and sacrificing the on-state performance of the device; (4) It allows for implementing a split gate structure in MOSFET cells with small JFET widths (see FIGS. 12 and 13), which typically improves device capacitance, as it removes lithography concerns for etching the gate between two channels; and (5) Significant reduction in cell pitch. The etching of the gate 34 poly above the traditional second channel creates a split-gate structure, with the gate poly now split and extending over the JFET region.

To illustrate the efficacy of the single-channel MOSFET design, 2-D Sentaurus simulations were conducted to optimize the device structure and performance. FIG. 3A is a graph 50 of a simulated electric field within the gate oxide for the conventional MOSFET (solid line) and one-channel MOSFET (dotted line). The electric field is shown from A-A′ Inf FIG. 1A (prior art), and B-B′ in FIG. 2A during blocking operation at an application bus voltage of 4500 V.

FIG. 3B is a graph 52 illustrating the peak electric field within the gate oxide during forward operation of the devices. Results from the simulations are shown in FIGS. 3A and 3B, indicating the electric field in the gate oxide is at acceptable values for reliable operation of the single-channel MOSFET 30.

The novel single-channel MOSFET 30 can be fabricated on a 4-inch SiC wafer, as an example, along with the conventional MOSFET layout (MOSFET 10) without altering or adding any process steps. Nitrogen implantations (n-type) can be used to form the N+ source and JFET regions, while aluminum (ptype) can be used to create the devices' P+ source, P-well, and JTE regions. Additionally, the P+ implant can be used in conjunction with a JTE implant to form a Ring-Assisted-JTE edge termination. Once ion implantation is completed, an activation anneal of 1650° C. for 10 minutes can be applied. A 50 nm thick gate oxide will then be formed, which can be followed by a 2 hour post oxidation anneal in NO. Gate 34 polysilicon was then deposited and patterned. Here, the single-channel structure can be formed by etching the gate 34 poly above the P-Well 38. After, an ohmic patterning step can be done and nickel, or other suitable metal, deposited. Both back and front ohmic contacts can undergo an ohmic anneal of approximately 1000° C. for 2 minutes. Following the anneal, a thick layer of aluminum (Al) can be deposited and patterned for both gate and source pads. To finish the MOSFET 34 devices, a passivation process can be completed on the wafer frontside and a backside solderable metal stack was deposited.

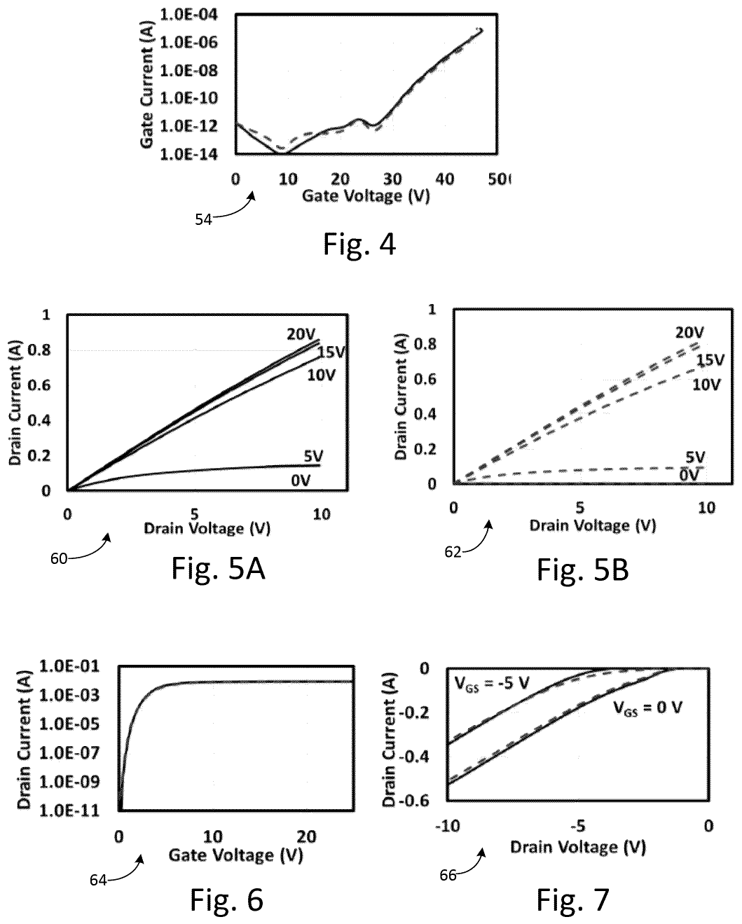

FIG. 4 is a graph 54 of a measured IGSS characteristics of a conventional MOSFET (solid line) and single-channel MOSFET (dotted line). FIG. 4 highlights the gate leakage characteristics of both fabricated MOSFET types, which show reliable gate operation for both MOSFETs. This reinforces effective gate design in the one-channel layout. The I-V curves for the fabricated devices at various gate voltages confirm that minimal effect on on-state performance is seen with the implementation of a one-channel approach, as shown in FIGS. 5A and 5B.

FIG. 5A is a graph 60 of the measured output curves of a conventional MOSFET. FIG. 5B is a graph 62 of the measured output curves of a single-channel MOSFET. The lowest R_{on,sp} achieved at a VGS of 20 V were 33.2 mΩ-cm2 (conventional) and 33.8 mΩ-cm2 (one-channel). No substantial difference is observed between the two device types, indicating the reduction of channel density in the single-channel MOSFET 34 is primarily offset due to its reduction in cell pitch compared to the conventional structure. A minimal difference in device performance is seen between gate voltages of 20 V and 15 V, indicating the devices can be used at a gate voltage of 15 V and still perform adequately.

FIG. 6 is a graph 64 of measured transfer curves for the conventional MOSFET (solid line) and one-channel MOSFET (dotted line). FIG. 6 displays the devices' transfer characteristics, demonstrating that the single-channel MOSFET 34 approach maintains the same channel control as a conventional MOSFET 10, as threshold voltages for both devices were typically 3 V (IDS=1 mA).

FIG. 7 is a graph 66 illustrating the third quadrant output of a conventional MOSFET 10 (solid line) and single-channel MOSFET 30 (dotted line). FIG. 7 shows that both devices demonstrate no substantial difference in output.

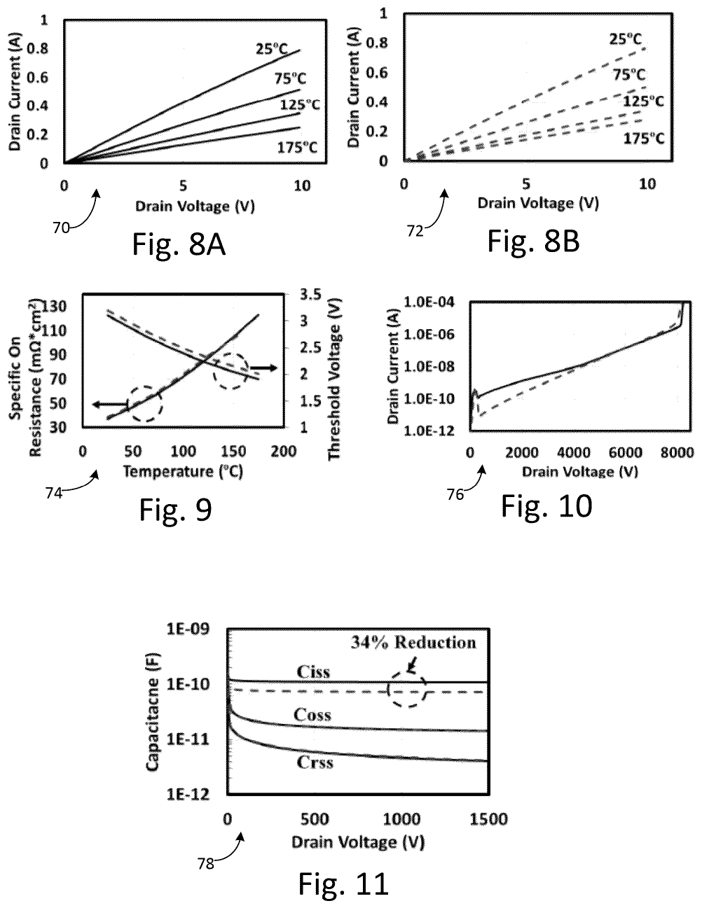

FIG. 8A is a graph 70 of the measured output curves of a conventional MOSFET 10 at various temperatures (solid lines). FIG. 8B is a graph 72 of the measured output curves of a single-channel MOSFET 34 at various temperatures (dotted lines). FIG. 9 is a graph 74 of the effect of temperature on specific on-resistance and threshold voltage are shown for the conventional MOSFET 10 (solid line) and single-channel MOSFET 30 (dotted line). FIGS. 8A-9 show both MOSFET devices' high-temperature performance, and no variation is demonstrated using either architecture.

FIG. 10 is a graph 76 of the measured forward blocking behaviors for the conventional MOSFET 10 (solid line) and single-channel MOSFET 30 (dotted line). The forward blocking characteristics of the devices are illustrated in FIG. 10 with both approaches exhibiting similar leakage currents and avalanche breakdown near 8000 V. Leakage current levels below 0.1 μA were observed at the target voltage (6.5 kV). No significant impact was seen using a one-channel MOSFET 30 layout from all static electrical data obtained.

FIG. 11 is a graph 78 of the measured capacitance curves for the conventional MOSFET (solid line) and single-channel MOSFET (dotted line). FIG. 11 highlights the capacitance measurements from fabricated single-channel MOSFET 30 and conventional MOSFET 10 in a custom package presented. A substantial improvement in Cᵢₛₛ is achieved through the use of a single-channel layout, one of the main benefits of the device. A reduction in Cᵢₛₛ leads to a reduction in gate voltage oscillations for high-frequency applications, a decrease in transient delay times, and reduced power loss from current-voltage overlaps during switching transients. No improvement was seen in the Cᵣₛₛ of the single-channel MOSFET 30 device despite a split gate approach. This likely originates from the MOSFETs' minimal Cᵣₛₛ due to the small JFET width and reduced cell pitch from using one-channel layout.

Thus, a single-channel MOSFET layout in a 6.5 kV 4H-SiC MOSFET created with removal of the gate 34 polysilicon above one of the traditional channels in a vertical power MOSFET cell allows for the potential of reduced capacitance of the power device. Both conventional and one-channel MOSFETs were fabricated on the same 4HSiC wafer and electrically characterized. IGSS measurements confirmed the viability of a one-channel gate structure. Measured forward IV, transfer characteristics, third quadrant behavior, high-temperature operation, and forward blocking confirm that at the 6.5 kV voltage rating, no decrease in forward operation, gate performance, and forward blocking is introduced with a one-channel layout. Lastly, from capacitance measurements, a significant reduction in Cᵢₛₛ is realized through a single-channel MOSFET 30 approach, showing the potential for dynamic performance improvement with this novel layout.

FIG. 12 is schematic diagram of one embodiment of a single-channel MOSFET 80 including a JFET 100. The MOSFET 80 cell has a single channel, with the cell on a substrate 82 and there is a first P-well 86 on the substrate, the first P-well having a top surface 88 thereof, and a first N-doped region 90 on, at least, a portion of the top surface 88 of the first P-well 86. There is also a second P-well 92 on the substrate adjacent to the first P-well, with the second P-well 92 having a top surface 96 thereof, and the second P-well 92 spaced from the first P-well to form a drain region. There is a second N-doped region 94 on, at least, part of the top surface 96 of second P-well 92 and a gate 84 is formed over a portion the first P-well 86 and a portion of the first N-doped region 90. The gate 84 extending a predetermined distance C over the drain 98 and a single channel is selectively created from the gate 84 to the drain region 98 upon the application of a predetermined voltage to the gate 84. Here, the predetermined distance is 0.5 μm, but the range of the extension of the gate 84 over the drain region 98 will vary based upon the design used.

In this embodiment, the MOSFET 80 is formed at a cell pitch of 4.5 μm, and the spaced of the components is illustrated with a scale 102. The gate 84 can be formed from polysilicon and the first P-well 86 and second P-well 92 can be Al or other like P-doped material. The first N-doped region 90 and second N-doped region 94 can be formed with nitrogen implantation.

As shown in the embodiment of MOSFET 80, the cell can be embodied with a JFET 100 formed over the drain 98. Further, the second P-well 92 and second N-doped region 94 can be used to form other electronic devices, such as a Schottky diode or P+ region.

FIG. 13 is a schematic diagram of one embodiment of the single-channel MOSFET 110 including a JFET 118 and a P+ implant 112 to the second P-well 114. In this embodiment, the gate 116 extends over the JFET 118, but not so far as over the P+ implant 112. The MOSFET 110 cell pitch in this embodiment is 5 μm, with a scale 120 illustrating the spacing of the components.

In a further embodiment, the invention can include a semiconductor structure formed in a MOSFET 30 that is otherwise configured to create two gate channels between a gate and two adjacent P-wells, as shown in the embodiment of FIG. 2A-2B.

In another embodiment, the invention includes a semiconductor device that has a plurality of MOSFET devices on a substrate, such as MOSFET 30 and MOSFET 46 in FIG. 2B. There is a first MOSFET device 30 on the substrate 32 which has a first P-well 38 on the substrate 32, and a second MOSFET device 46 on the substrate 32 adjacent to the second P-well 38 of the first MOSFET cell, with the second P-well 38 and second N-doped region 42 of the first MOSFET 30 device extending into the second MOSFET 46 device. The second MOSFET 46 formed over a portion of the second P-well 38 and second N-doped region 42 of the first MOSFET 30 device (which would have been the second channel of the first MOSFET) extending into the second MOSFET 46 device. The MOSFET 46 gate 47 does not extend over the extending portion of the second P-well 38 and second N-doped region 42 of the first MOSFET 30 device

FIG. 14 is a graph 130 of the R_{on,sp} as affected by JFET width. Illustrated is the single-channel design with and without a P+ implant 112 as compared to convention two-channel MOSFETs, both with a stripe P+ and an orthogonal P+ region.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A MOSFET cell having a single channel, comprising:
a substrate;
a first P-well on the substrate, the first P-well having a top surface thereof;
a first N-doped region on, at least, a portion of the top surface of the first P-well;
a second P-well on the substrate adjacent to the first P-well, the second P-well having a top surface thereof, the second P-well spaced from the first P-well;
a second N-doped region on, at least, part of the top surface of second P-well; and
a gate formed over a portion the first P-well and a portion of the first N-doped region, the gate extending a predetermined distance over a drain region;
wherein a single channel is selectively created upon an application of a predetermined voltage to the gate.

2. The MOSFET cell of claim 1, wherein the gate is formed from polysilicon.

3. The MOSFET cell of claim 1, wherein the first P-well and second P-well are implanted with Al.

4. The MOSFET cell of claim 1, wherein the first N-doped region and second N-doped region are formed with nitrogen implantation.

5. The MOSFET cell of claim 1, including a JFET region adjacent to the second P-well.

6. The MOSFET cell of claim 1, wherein the second P-well and second N-doped region form a Schottky diode.

7. The MOSFET cell of claim 1, wherein the second P-well includes a P+ implant.

8. The MOSFET cell of claim 1, further including a second MOSFET cell on the substrate adjacent to the second P-well, wherein:
the second MOSFET cell having a second gate;
the second P-well and second N-doped region extending into the second MOSFET cell; and
the second gate formed over a portion the second P-well and second N-doped region extending into the second MOSFET cell.

9. A semiconductor structure formed in a MOSFET configured to create two gate channels between a gate and two adjacent P-wells, the semiconductor structure comprising:
a substrate;
a first P-well on the substrate, the first P-well having a top surface thereof;
a first N-doped region on, at least, a portion of the top surface of the first P-well;
a second P-well on the substrate adjacent to the first P-well, the second P-well having a top surface thereof, the second P-well spaced from the first P-well;
a second N-doped region on, at least, part of the top surface of second P-well; and
a gate formed over a portion the first P-well and a portion of the first N-doped region over a portion of the first P-well, the gate further extending a predetermined distance over a drain region,
wherein a single channel is selectively created upon an application of a predetermined voltage to the gate.

10. The semiconductor structure of claim 9, wherein the gate is formed from polysilicon.

11. The semiconductor structure of claim 9, wherein the first P-well and second P-well are implanted with Al.

12. The semiconductor structure of claim 9, wherein the first N-doped region and second N-doped region are formed with nitrogen implantation.

13. The semiconductor structure of claim 9, including a JFET region adjacent the drain.

14. The semiconductor structure of claim 9, wherein the second P-well and second N-doped region form a Schottky diode.

15. The semiconductor structure of claim 9, wherein the second P-well includes a P+ implant.

16. A semiconductor device having a plurality of MOSFET devices, comprising:
a substrate;
a first MOSFET device on the substrate, the first MOSFET device having:
a first P-well on the substrate, the first P-well having a top surface thereof;
a first N-doped region on, at least, a portion of the top surface of the first P-well;
a second P-well on the substrate adjacent to the first P-well, the second P-well having a top surface thereof, the second P-well spaced from the first P-well;
a second N-doped region on, at least, part of the top surface of second P-well; and
a gate formed over a portion the first P-well and a portion of the first N-doped region, the gate extending a predetermined distance over a drain region;
wherein a single channel is selectively created upon an application of a predetermined voltage to the gate; and
at least a second MOSFET device on the substrate adjacent to the second P-well of the first MOSFET device, wherein:
the second P-well and second N-doped region of the first MOSFET device extending into the second MOSFET device; and
the second MOSFET cell further having a second gate, the second gate not over any portion of the second P-well and second N-doped region of the first MOSFET device extending into the second MOSFET device.

17. The semiconductor device of claim 16, wherein the first N-doped region and second N-doped region of the first MOSFET device are formed with nitrogen implantation.

18. The semiconductor device of claim 16, wherein a JFET region is formed in at least the first MOSFET device.

19. The semiconductor device of claim 16, wherein the second P-well and second N-doped region of the first MOSFET device form a Schottky diode.

20. The semiconductor device of claim 16, wherein the second P-well of the first MOSFET device includes a P+ implant.
